(19) United States
(12) Patent Application Publication
(10) Pub. No.: US 2020/0388492 A1
(43) Pub. Date: Dec. 10, 2020

(54) METHOD FOR MANUFACTURING SiC EPITAXIAL WAFER

(71) Applicant: SHOWA DENKO K. K., Tokyo (JP)

(72) Inventor: Yoshitaka NISHIHARA, Chichibu-shi (JP)

(73) Assignee: SHOWA DENKO K. K., Tokyo (JP)

(21) Appl. No.: 16/894,987

(22) Filed: Jun. 8, 2020

(30) Foreign Application Priority Data
Jun. 10, 2019 (JP) 2019-108114

(51) Int. Cl. H01L 21/02; H01L 21/66; H01L 21/04

(52) U.S. Cl. CPC H01L 21/02658; H01L 22/20; H01L 21/0475; H01L 21/02043; H01L 21/02529; H01L 21/02634; H01L 21/02378

(57) ABSTRACT

A method for manufacturing a SiC epitaxial wafer is provided. The method includes an observation step of observing a principal surface of a SiC substrate and identifying the presence or absence of a scratch having a depth of a predetermined value or more, a protrusion having a height of a predetermined value or more, or a foreign object having a height of a predetermined value or more, a polishing step of polishing the principal surface of the SiC substrate when it is identified that there is a scratch, the protrusion, or a foreign object and a layer forming step of forming a SiC epitaxial layer on the principal surface of the SiC substrate.

### BACKGROUND OF THE INVENTION

### Field of the Invention

The present invention relates to a method for manufacturing a SiC epitaxial wafer.

Priority is claimed on Japanese Patent Application No. 2019-108114, filed on Jun. 10, 2019, the content of which is incorporated herein by reference.

### Description of Related Art

Silicon carbide (SiC) has characteristics such as a dielectric breakdown electric field one order of magnitude larger, a band gap three times larger, and a thermal conductivity approximately three times higher than that of silicon (Si). Therefore, silicon carbide (SiC) is expected to be applied to power devices, high frequency devices, high temperature operation devices and the like.

In order to promote the practical application of SiC devices, it is essential to establish a high-quality crystal growth technique and a high-quality epitaxial growth technique.

A SiC single crystal substrate includes various defects. Various defects existing in the SiC epitaxial wafer are a cause of deterioration in quality. Among various defects are device killer defects that deteriorate the characteristics of SiC devices. Device killer defects include triangular defects. If the device killer defect exists on the SiC epitaxial wafer, the region including the device killer defect cannot be used, and thus it is a large factor that reduces the yield. Therefore, a method of manufacturing a high-quality SiC epitaxial wafer with few device killer defects is being studied.

Japanese Patent No. 6037671 discloses that triangular defects may be formed when a fragment of a member in a chamber for manufacturing a SiC epitaxial wafer falls on the surface of a SiC substrate. Japanese Patent No. 6037671 discloses that, by providing a shielding plate between the SiC substrate arranged in the chamber and a ceiling, it is possible to prevent the sealing member from dropping onto the SiC substrate to suppress the formation of triangular defects caused by particles.

### SUMMARY OF THE INVENTION

However, the triangular defect is a device killer defect having a large area. though it depends on the film thickness of the epitaxial layer, and is a particularly large factor that lowers the yield.

Therefore, there is a demand for a method of suppressing triangular defects formed due to factors other than particles. Examples of factors other than particles that cause the formation of triangular defects include defects and scratches on the SiC substrate. However, the relationship between the defects, scratches or the size of particles on the SiC substrate and the types of defects formed on the SiC epitaxial wafer is not known. Among the defects, scratches, and particles of the SiC substrate, it is required to identify one that causes a triangular defect and suppress the occurrence of the triangular defect.

The present invention has been made in view of the above circumstances, and an object thereof is to provide a method for manufacturing a SiC epitaxial wafer capable of suppressing the formation of triangular defects.

As a result of diligent studies, the inventors of the present invention have found that scratches with a depth of 0.4 μm or more, protrusions with a height of 0.4 μm or more, or foreign objects with a height of 0.4 μm or more existing on a SiC substrate are the starting points of formation of triangular defects when a SiC epitaxial layer is formed. The present invention provides the following means in order to solve the above problems.

(1) A method for manufacturing SiC epitaxial wafer according to a first aspect of the present invention comprises an observation step of observing a principal surface of a SiC substrate and identifying the presence or absence of a scratch having a depth of a predetermined value or more, a protrusion having a height of a predetermined value or more, or a foreign object having a height of a predetermined value or more, a polishing step of polishing the principal surface of the SiC substrate when it is identified that there is a scratch, the protrusion, or a foreign object, and a layer forming step of forming a SiC epitaxial layer on the main surface of the SiC substrate.

(2) The method for manufacturing a SiC epitaxial wafer according to the above aspect may further comprise a re-observation step of observing the principal surface of the SiC substrate again after performing the polishing step and observing the number of scratches having a depth of a predetermined value or more, protrusions having a height of a predetermined value or more, or foreign objects having a height of a predetermined value or more.

(3) In the method for manufacturing a SiC epitaxial wafer according to the above aspect, the principal surface of the SiC substrate may be polished so that the chip yield is 90% or more in the polishing step.

(4) A method for manufacturing SiC epitaxial wafer according to a second aspect of the present invention comprises a cleaning step of cleaning the SiC substrate; and an observation step of observing the principal surface of the SiC substrate and identifying the presence or absence of a protrusion or a foreign object having a height higher than a predetermined value, wherein further comprising a re-cleaning step of cleaning the SiC substrate again when it is identified in the observing step that there is a protrusion or a foreign object having a size larger than a predetermined value.

(5) The method for manufacturing a SiC epitaxial wafer according to the above aspect may further comprise a re-observation step of observing the principal surface of the SiC substrate again after performing the re-cleaning step and observing the number of scratches having a depth of a predetermined value or more, protrusions having a height of a predetermined value or more, or foreign objects having a height of a predetermined value or more.

(6) The method for manufacturing a SiC epitaxial wafer according to the above aspect, wherein in the re-cleaning step, the principal surface of the SiC substrate may be polished so that the chip yield is 90% or more.

(7) The method for manufacturing a SiC epitaxial wafer according to the above aspect, wherein the predetermined value may be 4 μm.

(8) The method for manufacturing a SiC epitaxial wafer according to the above aspect may further comprise a preliminary observation step of specifying the rough position of the scratch, the protrusion, or the foreign object before the observation step.

According to the method for manufacturing a SiC epitaxial wafer of the present invention, formation of triangular defects can be suppressed.

### BRIEF DESCRIPTION OF THE DRAWINGS

FIG. 1 is a perspective view of a SiC epitaxial wafer manufactured by the method for manufacturing a SiC epitaxial wafer according to this embodiment.

FIG. 2 is a SICA image of a SiC substrate which has a circular scratch on the principal surface thereof.

FIG. 3 is a SICA image of a SiC epitaxial wafer in which a SiC epitaxial layer is formed on the principal surface of the SiC substrate shown in FIG. 2.

FIGS. 4A to 4D are SICA images of the same SiC epitaxial wafer, and FIG. 4A is a SICA image of a part of the SiC epitaxial wafer which has scratch C. FIG. 4B is a SICA image of a part of the SiC epitaxial wafer which has scratch D, FIG. 4C is a SICA image of a part of the SiC epitaxial wafer which has scratch A and defect F. and FIG. 4C is a SICA image of a part of the SiC epitaxial wafer which has scratch E and defect G.

FIG. 5A is an image obtained by roughness-mapping a SiC epitaxial wafer. FIG. 5B is an enlarged view of the area X in FIG. 5A, and FIG. 5C is a confocal microscope image of the portion enlarged in FIG. 5B.

FIG. 6 is a result of having measured the vicinity of the scratch E including the scratch E of FIG. 4D by SICA.

### DETAILED DESCRIPTION OF THE INVENTION

Hereinafter, a method for manufacturing a SiC epitaxial wafer according to an embodiment of the present invention will be described in detail with reference to the drawings. In the drawings used in the following description, in order to make the features of the present invention easy to understand, there are cases where features are enlarged for the sake of convenience, and the dimensional ratios of the respective components may be different from the actual ones. The materials, dimensions, and the like exemplified in the following description are examples, and the present invention is not limited to them, and can be appropriately modified and implemented within the range in which the effect is exhibited.

### Method for Manufacturing a SiC Epitaxial Wafer (First Embodiment)

A method for manufacturing a SiC epitaxial wafer according to a first embodiment includes an observation step of observing a principal surface of a SiC substrate and identifying the presence or absence of a scratch having a depth of a predetermined value or more, a protrusion having a height of a predetermined value or more, or a foreign object having a height of a predetermined value or more, a polishing step of polishing the principal surface of the SiC substrate when it is identified that there is a scratch, the protrusion, or a foreign object, and a layer forming step of forming a SiC epitaxial layer on the main surface of the SiC substrate.

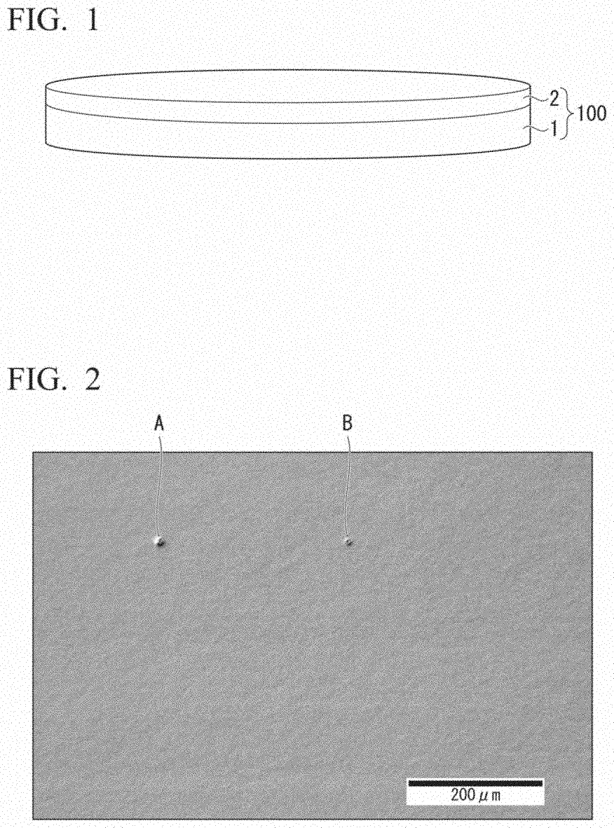

FIG. 1 is a perspective view of a SiC epitaxial wafer 100 manufactured by the method for manufacturing a SiC epitaxial wafer according to this embodiment. The SiC epitaxial wafer 100 has a SiC substrate 1 and a SiC epitaxial layer 2. The SiC substrate 1 is obtained by slicing a SiC single crystal produced by a sublimation method or the like. The SiC epitaxial layer 2 is a layer formed on the SiC substrate 1 by an epitaxial layer growing step. In this specification, the SiC substrate 1 means a wafer on which the epitaxial layer 2 is not formed, and the SiC epitaxial wafer 100 means a wafer on which the SiC epitaxial layer 2 is formed.

Hereinafter, in the specification, a thickness direction of the SiC epitaxial wafer 100 may be referred to as a z direction, a plane parallel to the principal(main) surface of the SiC epitaxial wafer 100 may be referred to as an xy plane, and one direction of the xy plane that is perpendicular to the z direction may be x direction, and the direction perpendicular to the x direction and the z direction may be referred to as the y direction.

### <Observation Step>

The observation step is a step of observing the principal surface of the SiC substrate and identifying the presence or absence of a scratch having a depth of a predetermined value or more, a protrusion or a foreign object having a height of a predetermined value or more. Here, the “scratch” is a portion having a recessed portion front the surface of the SiC substrate, and the “protrusion” is a portion of the SiC substrate and is a convex shape outward from the surface of the SiC substrate, and the “foreign object” is a substance other than the SiC substrate attached to the SiC substrate. That is, it may be possible to identify only the presence or absence of a scratch having a depth of a predetermined value or more, only the presence or absence of a protrusion having a height of a predetermined value or more, or only the presence or absence of a foreign object having a height of a predetermined value or more. By reducing the number of objects to be identified, the observation can be performed easily and throughput can be improved. In addition, it is preferable from the viewpoint of reducing the number chips that do not pass to identify the presence or absence of any two of any combination of a scratch having a depth of a predetermined value or more, a protrusion having a height of the predetermined value or more, and a foreign object having a height of the predetermined value or more. More preferably, the presence or absence of a scratch having a depth of a predetermined value or more, a protrusion having a height of a predetermined value or more, and a foreign substance having a height of a predetermined value or more are identified. The SiC substrate 1 to be observed in the observation step is not limited to this example, and a known SiC substrate can be used. For example, it is preferable that the SiC substrate 1 has an off angle of 0.4° or more and 8° or less. Typically, an off angle of 4° can be used. The thickness of the SiC substrate 1 is not particularly limited, but it is preferable to use, for example, one having a thickness of 150 μm or more and 550 μm or less. More preferably, those having a size of 300 μm or more and 400 μm or less can be used. The size of the SiC substrate 1 is not particularly limited, but, for example, those having a size of 3 inches to 6 inches can be used. The SiC substrate 1 may be washed before performing the observation step.

For a scratch having a depth of 0.4 μm or more, the depth of the scratch can be observed by using a device having the same principle as that of a laser microscope (VK-9710 manufactured by Keyence Corporation). In the present specification, the “scratch depth” means the deepest part from the surface of the SiC epitaxial wafer in a profile in the depth direction obtained using a laser microscope (for example, VK-9710 manufactured by Keyence Corporation). In the observation step, the presence or absence of the scratch having a depth of 0.4 μm or more is observed. The scratches for identifying the presence or absence on the SiC substrate 1 in the observation step are scratches of any shape as long as the scratches have a depth of 0.4 μm or more, but it is preferable that those are scratches having a width of 4 μm or more and 20 μm or less which do not depend on a crystal orientation. Examples of the shape of the scratch include a circular shape and a linear shape. The width here is the minimum value of the scratch in the lateral direction.

For a protrusion having a height of 0.4 μm or more and a foreign object having a height of 0.4 μm or more, and the height of the scratch can be observed by using a device having the same principle as that of a laser microscope (VK-9710 manufactured by Keyence Corporation). In the present specification, the “protrusion height” and the “foreign object height” means the highest part from the surface of the SiC substrate in a profile in the height direction obtained using a laser microscope (for example, VK-9710 manufactured by Keyence Corporation). In the observation step, the presence or absence of the protrusion having a height of 0.4 μm or more or the foreign object having a height of 0.4 μm or more is observed. The protrusions or foreign objects for identifying the presence or absence on the SiC substrate 1 in the observation step are protrusions or foreign objects of any shape as long as the protrusions or foreign objects have a height of 0.4 μm or more, but it is preferable that those are protrusions or foreign objects having a width of 4 μm or more and 20 μm or less which do not depend on a crystal orientation. The phrase “does not depend on the crystal orientation” means that the formation direction of the protrusions or the extension direction of the foreign object do not depend on the crystal orientation of the SiC substrate 1. The shape of the protrusion and the shape of the foreign object are arbitrary, and examples of the protrusion include a circular shape and a linear shape. The width here is the minimum value of the protrusion or the foreign object in the lateral direction. 10027J Among the protrusions or foreign objects of 0.4 μm or more on the principal surface of the SiC substrate 1, particles are defects that may form triangular defects when a SiC epitaxial layer grows on the SiC substrate.

FIG. 2 is a microscopic image (hereinafter referred to as SICA image) obtained by observing the principal surface of the SiC substrate 1 with an inspection apparatus (Laser Tech Co., Ltd., SICA88) provided with a confocal microscope and a photoluminescence (PL) observation function. The SiC substrate 1 shown in FIG. 2 has two scratches A and 8 on the principal surface. The scratch A has a depth of 0.4 μm or more, and the scratch B has a depth of less than 0.4 μm.

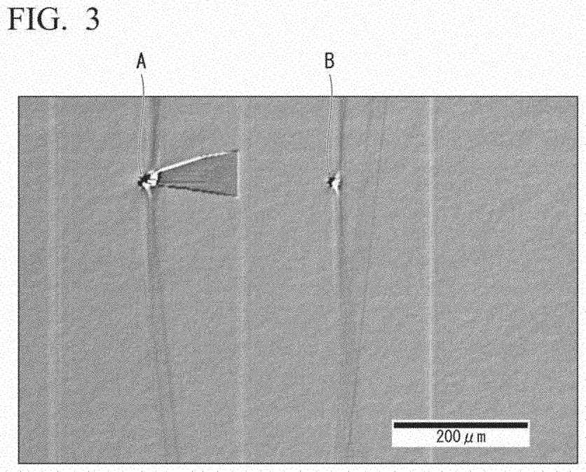

FIG. 3 is a SICA image of the upper surface of a SiC epitaxial wafer in which a SiC epitaxial layer is formed on the SiC substrate 1 shown in FIG. 2. Triangular defects starting from the scratch A are formed around the scratch A having a depth of 0.4 μm or more, and no triangular defect is formed around the scratch B having a depth of less than 0.4 μm.

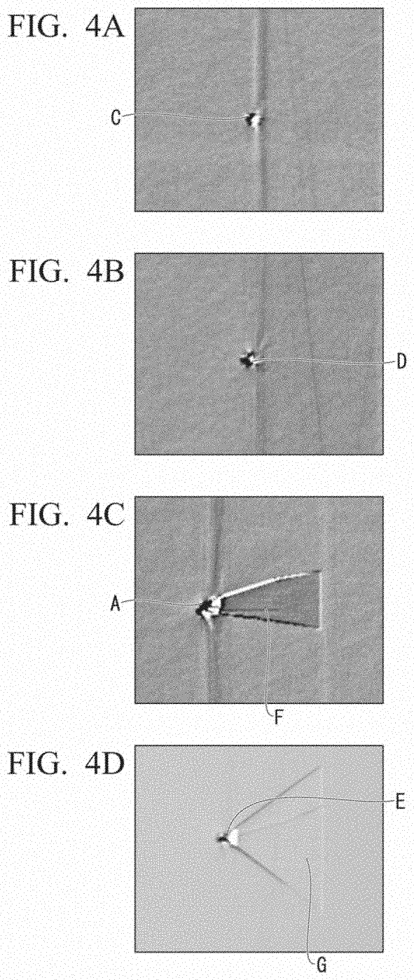

FIGS. 4A to 4D are SICA images of the same SiC epitaxial wafer 100, and the SiC epitaxial wafer 100 shown in FIGS. 4A to 4D has scratches A, C, D, E, and defects F and G. The defects F and G grow from the scratches A and E existing in the SiC substrate 1, respectively. FIG. 6 is a result of observing the scratch E of FIG. 4D by SICA. The horizontal axis represents the measurement position (μm), and the vertical axis represents the height (μm). The scratch E had a depth of 0.44 μm and a width of 4.5 μm. When the depths of the scratches A, C, and D were measured similarly to the scratch E, the depth of the scratch C was 0.27 μm, the depth of the drawing scratch D was 0.38 μm, and the depth of the scratch A was 0.44 μm. When the SiC epitaxial layers were formed, triangular defects F and G were formed starting from the scratches A and E.

A scratch having a depth of less than 0.4 μm, a protrusion having a height of less than 0.4 μm and a foreign object having a height of less than 0.4 μm on the principal surface of SiC substrate 1 do not form a triangular defect even when SiC epitaxial layer 2 is formed. On the other hand, scratches having a depth of 0.4 μm or more, protrusions having a height of 0.4 μm or more and foreign objects having a height of 0.4 μm or more on the principal surface of SiC substrate 1 may form triangular defects when the SiC epitaxial layer is formed. Therefore, it is preferable to set the predetermined value to 0.4 μm.

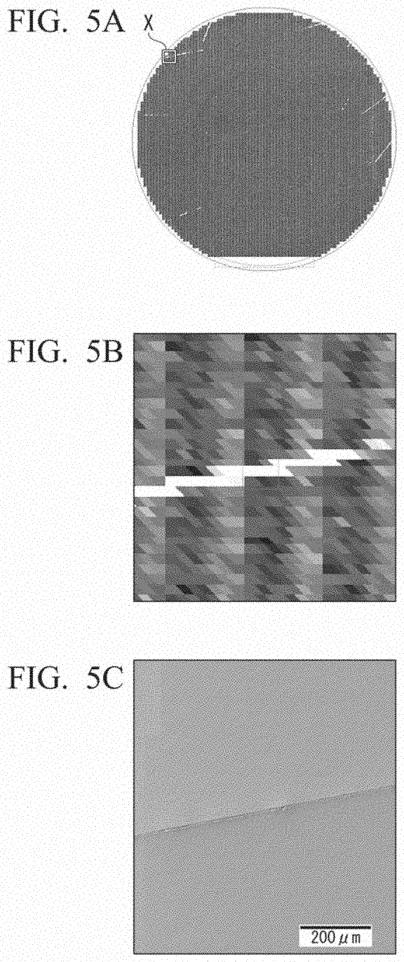

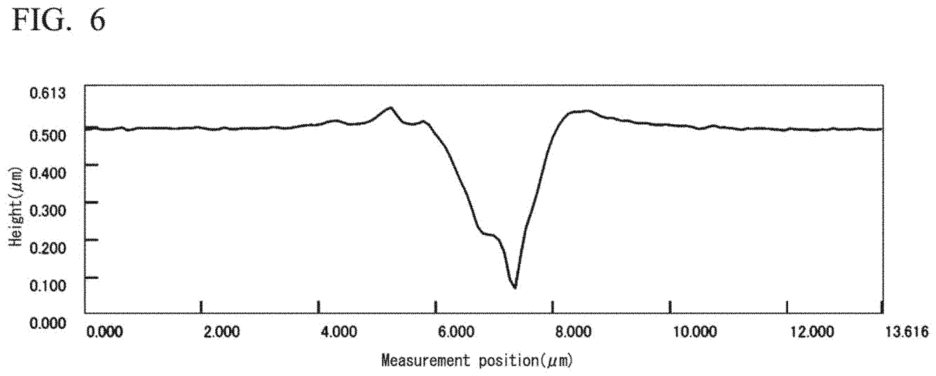

It is desirable that the observation step is performed after the rough position of the scratch, the protrusion, or the foreign object is specified. Any device capable of detecting scratches, protrusions, or foreign objects can be used to roughly determine the position. It is preferable that a confocal microscope attached to an inspection device that has a confocal microscope and a photoluminescence (PL) observation function (a device of the same principle as SICA88 manufactured by Lasertec Co., Ltd. (hereinafter sometime, referred to as SICA)) can be used. FIG. 5A is an image obtained by roughness-mapping a SiC epitaxial wafer with a confocal microscope attached to SICA. FIG. 5B is an enlarged view of the area X in FIG. 5A. White portions in FIGS. 5A and 5B are areas whom the Rq value exceeds 0.5 nm. The observation step according to the present embodiment is probably performed after rough areas that may be scratches, protrusions or foreign objects such as a white portion present in the roughness-mapped image of the SiC epitaxial wafer shown in FIGS. 5A and 5B, are specified.

FIG. 5C is a confocal microscope image of the portion enlarged in FIG. 5B. FIG. 5C is an image with the same magnification as FIG. 5B. After identifying the approximate location of what is considered to be a scratch, protrusion, or foreign object, the shape of what is considered to be a scratch, protrusion, or foreign object that can be seen in FIG. 5C is investigated in detail in an observation process. When it is identified that the investigated portion has a scratch with a depth of 0.4 μm or more, a protrusion with a height of 0.4 μm or more, or a foreign object with a height of 0.4 μm or more, the principal surface of the SiC substrate 1 is polished. By specifying the position of what is considered to be a scratch, protrusion, or foreign object and then measuring the depth or the height of the specified position, it is possible to efficiently specify a scratch having a depth of a predetermined value or more, a protrusion having a height of a predetermined value or more or a foreign object having a height of a predetermined value.

Moreover, the position where the triangular defect is formed after the SiC epitaxial layers are formed can be roughly specified by the observation step. That is, the chip yield can be predicted.

When it is identified in the observation step that there is a scratch having a depth of a predetermined value or more, a protrusion having a height of a predetermined value or more, or a foreign substance having a height of a predetermined value or more on the principal surface of the SiC substrate 1, a polishing step is performed. The polishing step is a step of polishing the principal surface of the SiC substrate 1, and polishing is performed so as to reduce scratches with a depth of 0.4 μm or more, protrusions with a height of 0.4 μm or more, and foreign object with a height of 0.4 μm or more from the surface of the SiC substrate 1. Polishing can be performed so that the chip yield is 80% or more, and preferably, polishing can be performed so that the chip yield is 90% or more, more preferably, polishing can be performed from the principal surface of SiC substrate 1 so that scratches having a depth of 0.4 μm or more, protrusions having a height of 0.4 μm or more, and foreign object having a height of 0.4 μm or more are removed from the principal surface of SiC substrate 1.

In the polishing step, the entire principal surface of SiC substrate 1 or a part of the principal surface can be polished. When a part of the SiC substrate 1 is polished, the part to be polished is determined based on the positions of the scratches having a depth of 0.4 μm or more, the protrusions having a height of 0.4 μm or more and the foreign object having a height of 0.4 μm more, which is identified in the observation step.

In the polishing step, a known method of polishing the principal surface of SiC substrate 1 can be performed. The polishing method is not limited to this example, and any polishing method can be selected. A polishing method including a plurality of polishing steps, for example, rough polishing called lap, precision polishing called polish, and chemical mechanical polishing (hereinafter referred to as CMP) which is ultra-precision polishing, can be performed. When this polishing method is performed, it can be performed, for example, under the following conditions. In mechanical polishing before CMP, it is preferable to suppress the strain of the lattice by setting the processing pressure to 350 g/cm² or less and using abrasive grains having a diameter of 5 μm or less. Further, in CMP, it is preferable that the polishing slurry contains abrasive particles having an average particle diameter of 10 nm to 150 nm and an inorganic acid, and that the pH at 20° C. is less than 2. It is more preferable that the abrasive particles are silica and the content thereof is 1 to 30% by mass. More preferably, the inorganic acid is at least one of hydrochloric acid, nitric acid, phosphoric acid and sulfuric acid.

The processing pressure at the time of polishing the SiC substrate 1, the polishing time and temperature, the types of abrasive particles and inorganic acid, the average particle size of the polishing slurry, and the like can be arbitrarily selected according to the size and number of scratches, protrusions, and foreign objects, the desired chip yield and the like. It should be noted that polishing with excessive strength is not preferable because it may cause damage or increase in scratches on the SiC substrate 1, so the range is set to the above range.

The polishing step can reduce scratches having a depth of 0.4 μm or more, protrusions having a height of 0.4 μm or more, or foreign objects having a height of 0.4 μm or more on the SiC substrate 1. For example, when there are only scratches having a depth of 0.4 μm or more, the SiC substrate 1 with reduced scratches having a depth of 0.4 μm or more can be provided. When there are only protrusions and foreign objects having a height of 0.4 μm or more, the SiC substrate 1 with reduced protrusions and foreign objects having a height of 0.4 μm or more can be provided. When there are scratches having a depth of 0.4 μm or more, and protrusions and foreign objects having a height of 0.4 μm or more are present, the SiC substrate 1 with reduced scratches having a depth of 0.4 μm or more and with reduced protrusions and foreign objects having a height of 0.4 μm or more can be provided.

After performing the polishing step, the observation step can be performed again. By performing the observing step again, the size and number of protrusions, foreign objects, and scratches on the principal surface of the SiC substrate 1 after the polishing step can be observed again to predict the chip yield. Further, the polishing step can be performed again depending on the size and number of scratches having a depth of 0.4 μm or more, and protrusions and foreign objects having a height of 0.4 μm or more, and depending on the chip yield. Note that the observation step here is not limited to performing the polishing step again as long as there is at least one scratch with a depth of 0.4 μm or more, a protrusion with a height of 0.4 pin or more, and a foreign substance with a height of 0.4 μm or more. Whether to perform the polishing step again can be arbitrarily selected according to the desired chip yield and the like. For example, when the chip yield is less than 90% or less than 95%, the polishing step can be performed again.

The SiC epitaxial layer 2 is formed by the layer forming process on the SiC substrate 1 in which scratches having a depth of 0.4 μm or more, protrusions having a height of 0.4 μm or more, and foreign objects having a height of 0.4 μm or more are reduced by the polishing process. The layer forming step is a step of forming the SiC epitaxial layer 2 on the principal surface of the SiC substrate 1. The layer formation of the SiC epitaxial layer 2 can be performed by a known method. For example, a SiC epitaxial layer 2 is formed on the principal surface of the SiC substrate 1 by step flow growth (lateral growth from atomic steps) by chemical vapor deposition (CVD) method or the like to obtain a SiC epitaxial wafer 100.

In the method for manufacturing a SiC epitaxial wafer according to the present embodiment, triangle defects are suppressed by polishing a SiC substrate having a scratch having a depth of a predetermined value or more, a protrusion having a height of a predetermined value or more or a foreign object having a height of a predetermined value or more to be flattened, and then forming a SiC epitaxial layer on the SiC substrate 1.

### Method for Manufacturing a SiC Epitaxial Wafer (Second Embodiment)

The method for manufacturing an SiC epitaxial wafer according to the second embodiment includes a cleaning(washing) step of cleaning the SiC substrate, and an observation step of observing the principal surface of the SiC substrate and identifying the presence or absence of protrusions or foreign object having a height higher than a predetermined value, and includes a re-cleaning step of cleaning the SiC substrate again when it is identified in the observing step that there is a protrusion or a foreign object having a size larger than a predetermined value.

The method for manufacturing the SiC epitaxial wafer according to the present embodiment has a cleaning step of cleaning the SiC substrate 1 before performing the observation step. Cleaning of the SiC substrate 1 can be performed by a known method. The SiC substrate 1 can be cleaned, for example, by RCA cleaning or ultrasonic cleaning. The RCA cleaning here is a wet cleaning method generally used for Si wafers. For RCA cleaning, a solution obtained by mixing sulfuric acid/ammonia/hydrochloric acid and hydrogen peroxide solution and a hydrofluoric acid aqueous solution are used. By the cleaning process, the projections on the substrate surface can be flattened and foreign objects can be removed.

In the observation step according to the present embodiment, the principal surface of the SiC substrate 1 is observed, and protrusions or foreign objects having a height of 0.4 μm or more among the defects identified in the observation step of the method for manufacturing the SiC epitaxial wafer according to the first embodiment are identified. Preferably, the presence or absence of protrusions and/or foreign objects having a height of 0.4 μm or more is identified. Other configurations can be the same as the observation step according to the first embodiment.

When it is identified in the observation step that there is a protrusion or a foreign substance having a height of a predetermined value or more on the principal surface of the SiC substrate 1, a re-cleaning step is performed. The re-cleaning step is a step of cleaning the SiC substrate 1 again. A known method can be used to clean the SiC substrate 1. Adjusting protrusions or foreign objects on the SiC substrate 1 with a height of 0.4 μm or more existing in a desired range can be performed, for example, by ultrasonic cleaning, overflow circulation of a chemical solution in a cleaning tank, particle removal by a filter, and the like. In the re-cleaning step, the time of re-cleaning, the type of chemical solution, the time or the frequency of the application of the ultrasonic wave, the pore size of the filter, etc. can be arbitrarily selected according to the size and the number of scratches, protrusions or foreign objects, the desired chip yield, and the like. For example, the chemicals that can be used are inorganic acids, inorganic alkalis, organic acids, organic alkalis and the like, the frequency for ultrasonic cleaning is 20 kHz or more and 2 MHz or less, and the time for ultrasonic cleaning is 1 minute or more and 30 minutes or less, and the pore size of the filter can be 50 nm or more and 5 μm or less. More preferably, the re-cleaning step is performed so that the chip yield is 80% or more, and it is more preferable so that the chip yield is 90% or more.

After performing the re-cleaning step, the observing step can be performed again. By performing the observing step again, the size and number of protrusions, foreign objects, and scratches on the principal surface of SiC substrate 1 can be observed again after the polishing step, and the chip yield can be predicted. Further, the polishing step can be performed again depending on the size and number of scratches having a depth of 0.4 μm or more, protrusions or foreign objects having a height of 0.4 μm or more, and chip yield. The observation step here is not limited to the re-cleaning step again as long as there is at least one scratch with a depth of 0.4 μm or more, a protrusion with a height of 0.4 μm or more, or a foreign object with a height of 0.4 μm or more whether to perform the re-cleaning step again can be arbitrarily selected depending on the desired chip yield and the like. For example, when the chip yield is less than 90% or less than 95%, the polishing step can be performed again.

The SiC epitaxial layer 2 is formed by the layer forming step on the SiC substrate 1 in which the protrusions and the foreign objects having a height of 0.4 μm or more are reduced by the re-cleaning step. In the layer forming step according to the present embodiment, the SiC epitaxial layer 2 can be formed on the principal surface of the SiC substrate 1 by the same operation as the layer forming step according to the first embodiment.

In the method for manufacturing the SiC epitaxial wafer according to the present embodiment, the re-cleaning step is performed before the SiC epitaxial layer is formed on the SiC substrate 1 having the protrusions or the foreign objects with the height equal to or higher than the predetermined value. It is possible to manufacture a SiC epitaxial wafer in which protrusions and foreign object are reduced and the formation of triangular defects is suppressed.

Although the preferred embodiments of the present invention have been described in detail above, the present invention is not limited to the specific embodiment, and various modifications and changes can be made within the scope of the effects of the present invention described in the claims.

What is claimed is:

1. A method for manufacturing a SiC epitaxial wafer, comprising:
an observation step of observing a principal surface of a SiC substrate and identifying the presence or absence of a scratch having a depth of a predetermined value or more, a protrusion having a height of a predetermined value or more, or a foreign object having a height of a predetermined value or more,
a polishing step of polishing the principal surface of the SiC substrate when it is identified that there is a scratch, the protrusion, or a foreign object, and
a layer forming step of forming a SiC epitaxial layer on the principal surface of the SiC substrate.

2. The method for manufacturing a SiC epitaxial wafer, according to claim 1, further comprising:
a re-observation step of observing the principal surface of the SiC substrate again after performing the polishing step and observing the number of scratches having a depth of a predetermined value or more, protrusions having a height of a predetermined value or more, or foreign objects having a height of a predetermined value or more.

3. The method for manufacturing a SiC epitaxial wafer according to claim 1, wherein in the polishing step, the principal surface of the SiC substrate is polished so that the chip yield is 90% or more.

4. A method for manufacturing a SiC epitaxial wafer, comprising:
a cleaning step of cleaning a SiC substrate; and
an observation step of observing the principal surface of the SiC substrate and identifying the presence or absence of a protrusion or a foreign object having a height higher than a predetermined value,
wherein further comprising a re-cleaning step of cleaning the SiC substrate again when it is identified in the observing step that there is a protrusion or a foreign object having a size larger than a predetermined value.

5. The method for manufacturing a SiC epitaxial wafer according to claim 4, further comprising:
a re-observation step of observing the principal surface of the SiC substrate again after performing the re-cleaning step and observing the number of scratches having a depth of a predetermined value or more, protrusions having a height of a predetermined value or more, or foreign objects having a height of a predetermined value or more.

6. The method for manufacturing a SiC epitaxial wafer according to claim 4, wherein in the re-cleaning step, the principal surface of the SiC substrate is polished so that the chip yield is 90% or more.

7. The method for manufacturing a SiC epitaxial wafer according to claim 1, wherein the predetermined value is 4 μm.

8. The method for manufacturing a SiC epitaxial wafer according to claim 1, further comprising:
a preliminary observation step of specifying the rough position of the scratch, the protrusion, or the foreign object before the observation step.
